(19) United States
(12) Patent Application Publication
(10) Pub. No.: US 2014/0174500 A1
(43) Pub. Date: Jun. 26, 2014

(54) CONCENTRATOR SYSTEM

(71) Applicant: Fraunhofer-Gesellschaft zur Forderung der angewandten Forschung E.V., Munchen (DE)

(72) Inventors: Tobias Fellmeth, Freiburg (DE); Daniel Biro, Freiburg (DE); Florian Clement, Freiburg (DE)

(73) Assignee: Fraunhofer-Gesellschaft zur Forderung der angewandten Forschung E.V., Munchen (DE)

(21) Appl. No.: 14/134,307

(22) Filed: Dec. 19, 2013

(30) Foreign Application Priority Data
Dec. 19, 2012 (DE) 102012223698.8

(51) Int. Cl. H01L 31/0224; H01L 31/052

(52) U.S. Cl. CPC H01L 31/02245; H01L 31/0525
USPC 136/246

(57) ABSTRACT

A concentrator system having an optical concentrator and a receiver with a carrier substrate and at least one photovoltaic solar cell. The optical concentrator and the receiver are arranged to concentrate incident electromagnetic radiation onto a front side of the solar cell. The solar cell has at least one base and at least one emitter region and at least one metallic base contact structure electrically conductively connected to the base region for external interconnection, and at least one metallic emitter contact structure is electrically conductively connected to the emitter region external contact. The base and emitter contact structures are arranged on the front side of the solar cell. At least one base back-side metallization is provided, and the solar cell has at least one metallic base via structure that extends from the base back-side metallization to the base contact structure for electrically conductive connection by the base via structure.

### INCORPORATION BY REFERENCE

The following documents are incorporated herein by reference as if fully set forth: German Patent Application No. 102012223698.8, filed Dec. 19, 2012

### BACKGROUND

The invention relates to a concentrator system for incident electromagnetic radiation.

Concentrator systems having an optical concentrator unit and a receiver are known for converting incident electromagnetic radiation, in particular sunlight. The receiver in turn has a carrier substrate and at least one photovoltaic solar cell.

The incident electromagnetic radiation is concentrated by the concentrator unit onto the at least one photovoltaic solar cell, such that a higher light intensity compared with the incident radiation is present on a front side of the photovoltaic solar cell, said front side being designed for light incidence.

Such concentrator systems have the advantage, inter alia, that radiation incident on an incidence area of the concentrator unit is concentrated onto a solar cell having a considerably smaller area compared with the incidence area, such that, in particular, less material for producing the solar cell is required compared with non-concentrating systems.

Highly concentrating concentrator systems, in which a concentration factor of 100 or more is typical, are usually employed in conjunction with photovoltaic III-V solar cells, in particular using solar cell structures having a plurality of p-n junctions.

In this case, the receiver typically has a plurality of photovoltaic solar cells interconnected in a module. Such a concentrator system is described in WO 2008/107205 A2.

### SUMMARY

The present invention is based on the object of providing cost-effective alternatives to previously known concentrator systems and, in particular, of extending the field of application of previously known concentrator systems in particular with silicon-based solar cells.

This object is achieved by a concentrator system according to the invention. Advantageous configurations of the concentrator system according to the invention are described below and in the claims.

The concentrator system according to the invention comprises an optical concentrator unit and a receiver, which receiver has a carrier substrate and at least one solar cell. The optical concentrator unit and the receiver are arranged in an interacting fashion in such a way that during the use of the concentrator system incident electromagnetic radiation can be concentrated by the concentrator unit onto at least one partial region of a front side of the solar cell.

The solar cell is designed as a photovoltaic semiconductor solar cell, having at least one base region and at least one emitter region and also at least one metallic base contact structure, which is electrically conductively connected to the base region, and at least one metallic emitter contact structure, which is electrically conductively connected to the emitter region. The base and emitter contact structures are in each case designed for external electrical contact-making, for example by a cell connector.

It is essential that in the concentrator system according to the invention that the base contact structure and the emitter contact structure are arranged indirectly or directly on the front side of the solar cell, that at least one base back-side metallization, which is electrically conductively connected to the base, is arranged indirectly or directly at the back-side of the solar cell, and that the solar cell has at least one base via structure, which base via structure extends from the base contact structure, such that base back-side metallization and base contact structure are electrically conductively connected by the base via structure. The base via structure is likewise formed in a metallic fashion, such that proceeding from the back-side metallization there is a metallic electrically conductive connection to the base contact structure.

The invention is based on the applicant's insight that the currents typically arising at the solar cells in concentrator systems, which currents are higher than in non-concentrating solar cell applications, can especially lead to reductions of efficiency on account of series resistance losses. At the same time, the thermal load on solar cells in concentrator applications is typically considerably more than in non-concentrating applications, such that a large-area thermal contact with heat dissipating elements is required.

In contradistinction to typical non-concentrating applications, however, in concentrator systems it is not necessary to ensure that as little area as possible at the front side of the solar cell is shaded by metallic contact structures. This is because at the edges of the front side of the solar cell it is possible to exclude regions of the solar cell surface from impingement with light, which regions can thus be occupied by metallic contact structures having sufficient dimensioning, without thereby bringing about a considerable increase in costs and a reduction of the efficiency of the overall system.

In the concentrator system according to the invention, therefore, for the first time the current of the back-side metallization is conducted by a metallic base via structure to a base contact structure arranged at the front side of the solar cell. This affords a number of advantages:

Firstly, the interconnection of a plurality of solar cells within the concentrator system is considerably simpler since the metallic contact structures of both polarities, that is to say base and emitter contact structures, are arranged at the front side of the photovoltaic solar cell and a contact structure can thus be connected in a simple manner to an identical contact structure or—in the case of the typical series circuit—a contact structure of the opposite polarization of a neighboring solar cell.

Furthermore, no cell connectors have to be led to the base back-side metallization, with the result that the base back-side metallization can be arranged over the whole area on a heat dissipating element, preferably a thermally conductive and simultaneously electrically insulating element, such as, for example, anodized aluminum or coated ceramics. This enables maximum heat dissipation via the base back-side metallization, preferably formed over the whole area at the back-side of the solar cell.

It lies within the scope of the invention for the base via structure to be arranged laterally alongside the base region. This affords the advantage that the base via structure can extend over the entire width of the base region in a simple manner, and a low conduction resistance is thus obtained in a simple manner.

It is particularly advantageous that the base via structure is formed in a manner penetrating through the base. For this purpose, the solar cell preferably comprises a plurality of base via structures which in each case penetrate through the base. Preferably, the base via structures penetrate through the base approximately perpendicularly to the back-side.

In particular, it is advantageous that the base via structure penetrates through at least the photovoltaically active base region, i.e. that region in which the generation of charge carrier-hole pairs substantially takes place.

This affords the advantage that during the processing of the solar cell it is possible to have recourse to previously known process steps in which cutouts are formed in the base, for example by a laser, and they are subsequently filled with metal, for example by the introduction of a paste containing metal particles, for example by a printing method, for example by the screen printing or stencil printing method. Furthermore, electrodeposition of the metal particles is possible. The via structures typically have a diameter in the range of 30-100 μm. In particular, it is possible to have recourse to a multiplicity of optimized processing steps of MWT (metal wrap through) solar cells. One process for producing an MWT solar cell is described for example in Florian Clement (DOI: 10.1016/j.solmat.2009.06.020) or Benjamin Thaidigsmann (DOI: 19.1002/pssr.201105311).

The concentrator system according to the invention is suitable, in particular, for solar cells which comprise a silicon substrate. Typically previously known concentrator system are based on III-V semiconductor solar cells, which, however, are complex and hence expensive to produce. In accordance with WO 2008/107205 A2, silicon substrates can be used in these systems as a mechanical and accordingly supporting element, but not as a photovoltaically active element. With the concentrator system according to the invention, it is now possible for the first time, in a simple manner, also to employ solar cells based on a silicon substrate cost-effectively in a concentrator system, in particular due to the simpler interconnection and improved heat dissipation and also the possible recourse to previously known, in many cases already optimized processing steps for producing such a silicon solar cell, in particular in the configuration of the base via structure penetrating through the base.

Preferably, therefore, the solar cell of the concentrator system according to the invention comprises a silicon substrate, in which silicon substrate the base is formed, particularly preferably both the base and the emitter are formed in the silicon substrate.

In this advantageous configuration as a typical silicon solar cell, the solar cell is thus designed in such a way that during use generation of charge carrier pairs on account of the absorption of the incident radiation takes place substantially in the silicon substrate.

As already mentioned, for optimum heat dissipation, the base back-side metallization is preferably connected to a heat dissipating substrate, particularly preferably connected to the heat dissipating substrate over the whole area.

In a further preferred embodiment of the concentrator system according to the invention, the solar cell comprises a semiconductor layer, at the back-side of which at least one base region and at least one emitter region are formed. Furthermore the solar cell comprises an emitter back-side metallization and also at least one metallic emitter via structure. The emitter back-side metallization is arranged indirectly or directly at the back-side of the semiconductor layer and is electrically conductively connected to the emitter region. The emitter via structure extends from the emitter back-side metallization to the emitter contact structure, such that emitter back-side metallization and emitter contact structure are electrically conductively connected by the metallic emitter via structure.

In this preferred embodiment, therefore, charge carriers of both polarities are passed by a metallic via structure from the back-side to the metallic contact structures arranged at the front side.

This affords the advantage that those previously known solar cell structures which also have at least one emitter region at the back-side can also be used in the concentrator system according to the invention. In principle, such a solar cell structure (apart from the metallic base and emitter via structures) is known as “back contact back junction solar cell” (BCBJ) or as “interdigitated back contact” (IBC) and is described for example in M. Lammert and R. Schwartz, “The Interdigitated Back Contact Solar Cell: Silicon Solar Cell for Use in Concentrated Sunlight”, IEEE TRANSACTIONS ON ELECTRON DEVICES, VOL. ED-24, NO. 4, APRIL 1977.

Such a solar cell structure has the advantage that the metallic structures required for areally carrying away current are arranged on the back-side of the solar cell structure and as a result there are no shading losses at all. They can turn out to be larger as a result, which leads to lower ohmic losses particularly under concentrated irradiation. A further advantage is based on the fact that weakly doped and thus a semiconductor substrate can be used which provides very high lifetimes for generated charge carriers.

The external contact elements constitute one disadvantage in the previous embodiment, said external contact elements leading to lateral current flow in the semiconductor substrate and thus to higher series resistances. Furthermore, the electrical contact-making arranged at the back-side makes it more difficult to bring about efficient thermal linking, which is inherently important particularly under concentrated irradiation.

In this preferred embodiment, it is particularly advantageous that a plurality of alternately arranged emitter and base back-side metallizations are arranged at the back-side of the solar cell. In particular, it is advantageous that emitter and base back-side metallizations extend parallel to one another. This enables charge carriers to be carried away efficiently since, in particular, losses of efficiency on account of lateral currents in the semiconductor layer are reduced or avoided.

The combined use of emitter and base via structures results, in particular, in a clear delimitation with respect to the prior art with regard to EWT and MWT e.g. described in DE 102009 030996 A1 and WO 2012/143 460 A2, which generally have only one or a plurality of emitter via structures. As a result, both contacts are placed from the back-side onto the front side and a front contact back junction MWT solar cell arises.

Furthermore, in this preferred embodiment it is advantageous that each emitter back-side metallization is connected to in each case at least one emitter via structure and each base back-side metallization is connected to in each case at least one base via structure. As a result, a low conduction resistance is obtained on account of the parallel connection of the respective via structures and a loss of efficiency on account of electrical series resistances is thus decreased further. Preferably, the receiver of the concentrator system according to the invention comprises a plurality of solar cells, i.e. a plurality of the above-described solar cell or of a preferred embodiment thereof. The plurality of solar cells are electrically interconnected to form a solar cell module, preferably in series connection.

In particular, it is advantageous that the plurality of solar cells are arranged serially as a solar cell series.

This firstly affords the advantage that a simple electrical series connection of the solar cells arranged locally serially alongside one another is possible, and furthermore makes it possible to use cost-effective optical concentrator units which concentrate incident light onto an elongated region of the serially arranged solar cell series.

Preferably, in this case, the serially arranged solar cells in each case have the emitter and base contact structures at the front side at at least one outer region, i.e. a region which lies at the edge of the solar cell series and thus does not directly adjoin a further solar cell. For the purposes of an electrical series connection, in each case an emitter contact structure of one solar cell is electrically conductively connected to the base contact structure of the following solar cell by a cell connector, and vice versa.

As a result, an electrical series connection of the solar cells is thus obtained in a simple manner, without shading by a cell connector taking place in the central region exposed to radiation by the optical concentrator unit. This is because the abovementioned outer regions in which emitter contact structure or base contact structure is arranged and which enable the electrical connection to the neighboring solar cell by a cell connector are preferably arranged in a manner interacting with the optical concentrator unit in such a way that the light concentration takes place within said outer regions and, consequently, there is no shading by emitter and base contact structures, nor by the cell connectors. A cell connector constitutes an electrically conductive element which electrically conductively connects one solar cell to a neighboring solar cell. Cell connectors are typically formed in a metallic fashion, in particular approximately in a strip-shaped fashion.

In this case, the cell connector can be applied on the respective emitter or base contact structure. This results in a large-area contact, such that possible series resistance losses are avoided.

In an alternative embodiment, the cell connector is arranged alongside the solar cell series and extends in each case over two solar cells. The emitter and base contact structures respectively of the solar cells are electrically conductively connected to the cell connector by bonding, for example.

This affords the advantage that the current-carrying “cell connector” is arranged alongside the photovoltaically active region and can be given larger dimensions as a result. What arises from this is that the metallic structures on the front side can be reduced in size and a larger photovoltaically active area results.

In a further preferred embodiment, the solar cells of the solar cell series in each case have the emitter contact structure at one edge region and the base contact structure at an opposite edge region, and the solar cells are arranged alternately with regard to the contact structure, in such a way that a cell connector extending approximately rectilinearly over an edge region of the solar cell series in each case electrically conductively connects an emitter contact structure to a base contact structure of the neighboring solar cell. As a result, a series connection of the solar cells of the concentrator system is possible in a technically unobtrusive manner.

The base via structure, preferably all the base via structures, is/are preferably formed concomitantly in a manner comprising silver. In a further preferred embodiment, the base via structure, preferably all the base via structures, is/are formed from the same material as the base back-side metallization, particularly preferably in a manner comprising aluminum.

The concentrator system according to the invention has the advantage, in particular, of enabling a particularly compact arrangement of the solar cells on account of the novel interconnection scheme. In previous interconnection arrangements, a minimum distance, typically in the range of 1 mm to 2 mm, between the solar cells is always required, for example in order to lead through cell connectors between the solar cells. By contrast, the concentrator system according to the present invention makes it possible to arrange the solar cells with a smaller distance, in particular a distance of less than 0.5 mm, in particular less than 0.1 mm, alongside one another.

### BRIEF DESCRIPTION OF THE DRAWINGS

Further preferred features and embodiments of the invention are described below on the basis of exemplary embodiments and the figures, in which:

FIG. 1 shows a first exemplary embodiment of a concentrator system according to the invention;

FIG. 2 shows a sectional view of a solar cell of the concentrator system from FIG. 1;

FIG. 3 shows a second exemplary embodiment of a solar cell for a concentrator system according to the invention in accordance with FIG. 1;

FIG. 4 shows a plan view from above of the solar cells in accordance with FIG. 2 and FIG. 3;

FIG. 5 shows a first exemplary embodiment of a series connection of solar cells for a concentrator system according to the invention;

FIG. 6 shows a further exemplary embodiment of a solar cell for a concentrator system according to the invention;

FIG. 7 shows a plan view from above of the solar cell in accordance with FIG. 6;

FIG. 8 shows an exemplary embodiment of a series connection for the solar cell in accordance with FIG. 6 and FIG. 7;

FIG. 9 shows an exemplary embodiment of a cell connector for series interconnection in accordance with FIG. 8;

FIG. 10 shows a detail view of the exemplary embodiment in accordance with FIG. 1;

FIG. 11 shows a further exemplary embodiment for the series interconnection of solar cells for a concentrator system according to the invention for solar cells in accordance with FIG. 2 and FIG. 3;

FIGS. 12A and 12B show a further exemplary embodiment of a solar cell for a concentrator system according to the invention (FIG. 12B) and, in FIG. 12A, an exemplary embodiment of series interconnection of the solar cells from FIG. 12B for a concentrator system according to the invention;

FIG. 13 shows a further exemplary embodiment of a series interconnection of the solar cells from FIG. 12B, for a concentrator system according to the invention, and

FIGS. 14A and 14B show a further exemplary embodiment of a series interconnection of a modification of the solar cells from FIG. 12B, for a concentrator system according to the invention.

### DETAILED DESCRIPTION OF THE PREFERRED EMBODIMENTS

All the figures show schematic illustrations that are not true to scale. In the figures, identical reference signs designate identical or identically acting elements.

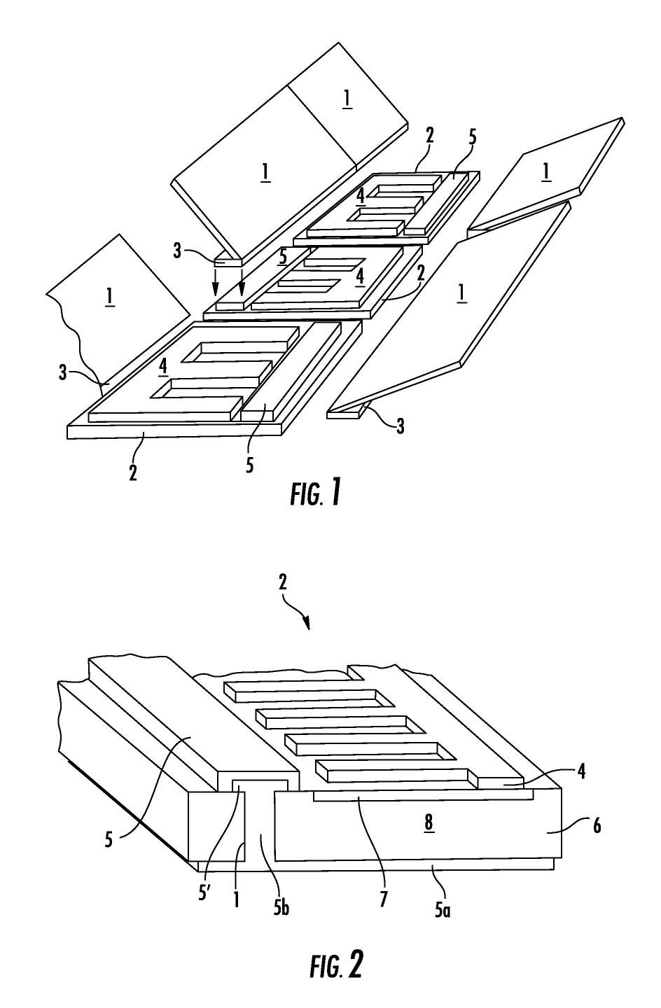

FIG. 1 shows an exemplary embodiment of a concentrator system according to the invention. The concentrator system comprises an optical concentrator unit comprising a plurality of optical mirrors 1. The mirrors can consist of a carrier material, for example, to which a reflective film is adhesively bonded or which is coated with a metal, for example by vapor deposition or sputtering.

The concentrator system comprises a plurality of solar cells 2, three of which are illustrated in FIG. 1.

The solar cells 2 have at the front side in each case a metallic emitter contact structure 4 and in each case a metallic base contact structure 5. The solar cells are arranged in an alternating order in each case by 180° about a perpendicular axis, such that in the sequence of the solar cells the base contact structure 5 is arranged alternately on the right and left at the edge of the solar cell series and in an opposite alternating sequence the emitter contact structure 4 is correspondingly arranged alternately on the left and right.

As a result, in a simple manner, by a cell connector 3, an emitter contact structure 4 can in each case be connected to the base contact structure 5 of the neighboring solar cell, the cell connector 3 having a simple parallelepipedal construction.

For the sake of better clarity, the cell connectors 3 are illustrated in a manner moved away toward the side and upward like an exploded drawing in FIG. 1. For the upper left cell connector 3′, the actual position of the cell connector is indicated by arrows.

The mirroring structure 1 can on the one hand itself serve as a cell connector, or be subsequently fitted thereabove. The mirroring structure can on the one hand be regarded as a primary reflective structure, or else in a supporting fashion as a secondary reflector as a so-called “secondary”, such that the incident rays are concentrated in a simple manner by the mirrors 1 onto the front side of the solar cells that is not covered by the cell connectors 3.

As a result, a concentrator system comprising serially arranged solar cells that are electrically interconnected in series is formed in a simple and cost-effective manner.

This simple construction is made possible, in particular, by the construction of the solar cell structure of the concentrator system according to the invention, as explained below on the basis of exemplary embodiments of solar cells for a concentrator system according to the invention in accordance with FIGS. 2, 3, 4, 6, 7 and 12:

FIG. 2 shows a first exemplary embodiment of a solar cell for a concentrator system according to the invention.

The solar cell 2 is formed on a p-doped silicon wafer 6, in which an emitter 7 was introduced by diffusion and overcompensation. The remaining region 8 of the silicon wafer 6 thus constitutes the base, which adjoins the emitter 7, with the result that a p-n junction is formed here.

A metallic emitter contact structure 4 is arranged at the front side of the solar cell, said emitter contact structure being electrically conductively connected to the emitter 7.

A metallic base back-side metallization 5a is arranged at the back-side of the solar cell, said base back-side metallization being electrically conductively connected to the base 8.

The solar cell 2 can be designed, in principle, in accordance with previously known solar cells and comprise further previously known elements—not illustrated—such as, for example, passivating layers for reducing the surface recombination rate and/or optical layers and/or texturing for increasing the coupling-in of radiation at the front side of the solar cell 2 and/or the optical reflection within the solar cell.

It is essential that the metallic base contact structure 5 and the metallic emitter contact structure 4 are both arranged on the front side of the solar cell, and that the solar cell has at least one metallic base via structure 5b. The base via structure 5b extends from the base back-side metallization 5a to the base contact structure 5.

Base contact structure 5 and base back-side metallization 5a are thus electrically conductively connected by the base via structure 5b, such that, in a simple manner, from the front side, an electrical contact both to the base 8 and to the emitter can be produced and, in particular, a technically non-complex and thus cost-effective construction of the concentrator system in accordance with FIG. 1 can be realized.

In the exemplary embodiment in accordance with FIG. 2, base back-side metallization 5a and base via structure 5b are formed in an integral fashion, in particular from the same material, together with a first base contact structure region 5. The first external base contact structure region 5 consists of a different metal, in order to facilitate the electrical connection to the cell connector 3.

It likewise lies within the scope of the invention to design the solar cell with opposite doping types, i.e. with an n-doped base and a p-doped emitter.

FIG. 3 illustrates a further exemplary embodiment of a solar cell 2 for the concentrator system in accordance with FIG. 1. In order to avoid repetition, only the differences with respect to FIG. 2 will be discussed here:

In the case of the solar cell in accordance with FIG. 3, base contact structure 5, base back-side metallization 5a and base via structure 5b are formed in each case as dedicated elements composed of different electrically conductive materials which adjoin one another and are thus electrically conductively connected.

The emitter 7 covers the entire front side of the solar cell and extends under the base contact structure 5. An electrical insulation between base contact structure 5 and emitter 7 is effected by a dielectric layer or a dielectric layer stack. This layer or this layer stack functions as passivation of the underlying semiconductor, for the reduction of the reflection by light and, at the same time, as electrical insulation or spatial separation of the polarities.

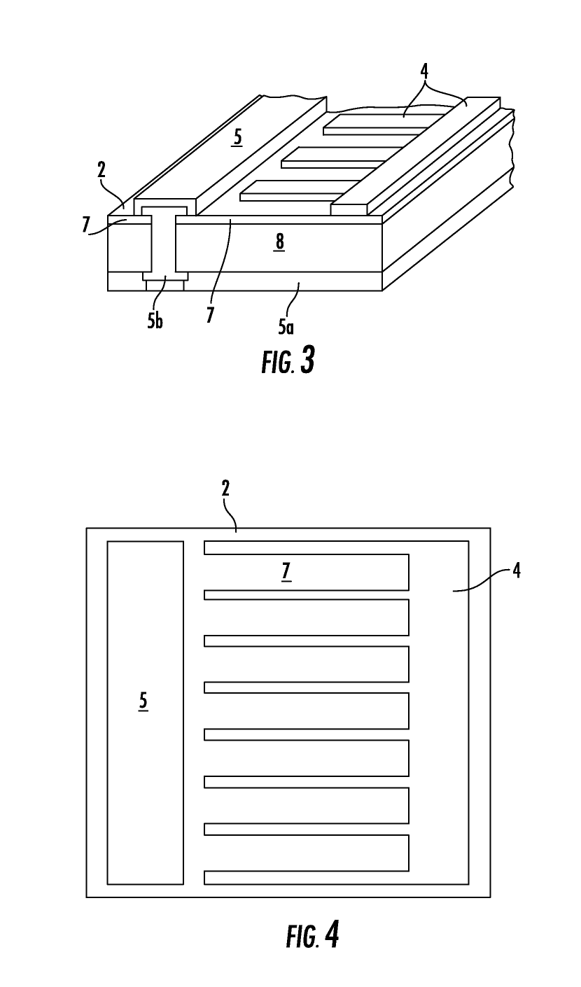

FIG. 4 illustrates a plan view from above of a solar cell in accordance with FIG. 2 or in accordance with FIG. 3.

FIG. 5 shows a further modification of the exemplary embodiment in accordance with FIG. 1, in which a bypass diode 9 is additionally electrically interposed between two cell connectors 3.

The bypass diode prevents excessive heating of individual solar cells or of individual regions of a solar cell in particular in the case of partial shading. Consequently, so-called “hot spots” are avoided by the bypass diode.

Apart from the additionally arranged bypass diode 9, FIG. 5 shows a plan view from above of the series interconnection of the serial solar cells in a concentrator system in accordance with FIG. 1.

The serially arranged solar cells thus have in each case the emitter contact structure 4 and, situated opposite, the base contact structure 5 at the front side at an outer region of the solar cell series. The emitter contact structure of a solar cell is in each case electrically conductively connected to the base contact structure of the following solar cell by a cell connector 3.

In this instance, a cell connector 3 in each case extends over two solar cells.

The solar cells 2 are arranged alternately with regard to the contact structures 4 and 5, in such a way that the cell connectors 3 extending approximately rectilinearly over in each case an edge region of the solar cell series in each case electrically conductively connect an emitter contact structure 4 to a base contact structure 5 of the adjacent solar cell.

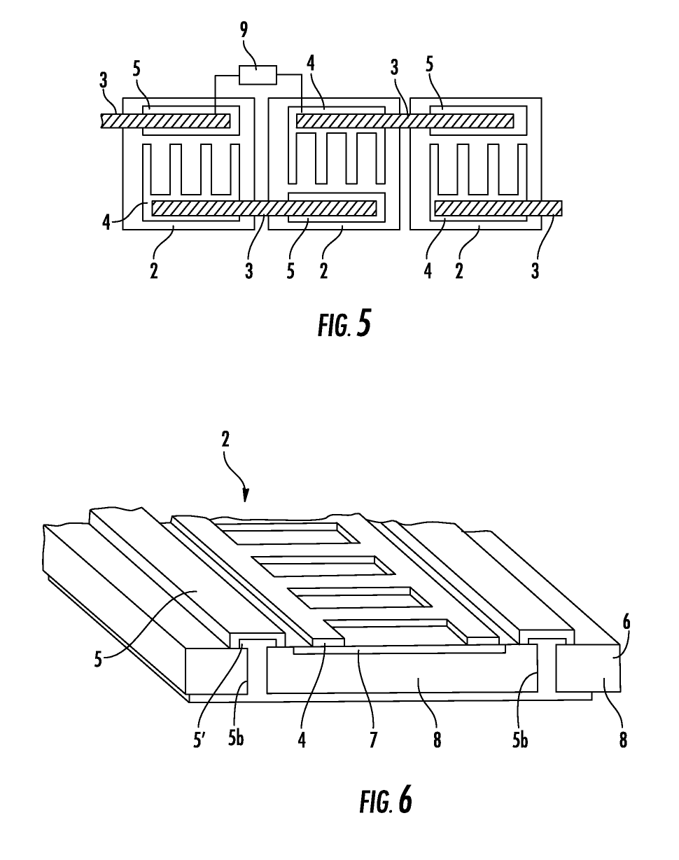

FIG. 6 shows a further exemplary embodiment of a solar cell for a concentrator system according to the invention. In principle, the solar cell is constructed similarly to the solar cells in accordance with FIGS. 1 and 2 and can also be embodied on the basis of FIG. 3 in a further exemplary embodiment.

An essential difference is that metallic base via structures 5b are in each case arranged at two opposite edge regions and a base contact structure 5 is in each case arranged correspondingly at the front side of the solar cell 2 at the two opposite edge regions, said base contact structure being electrically conductively connected to the respectively underlying base via structure 5b.

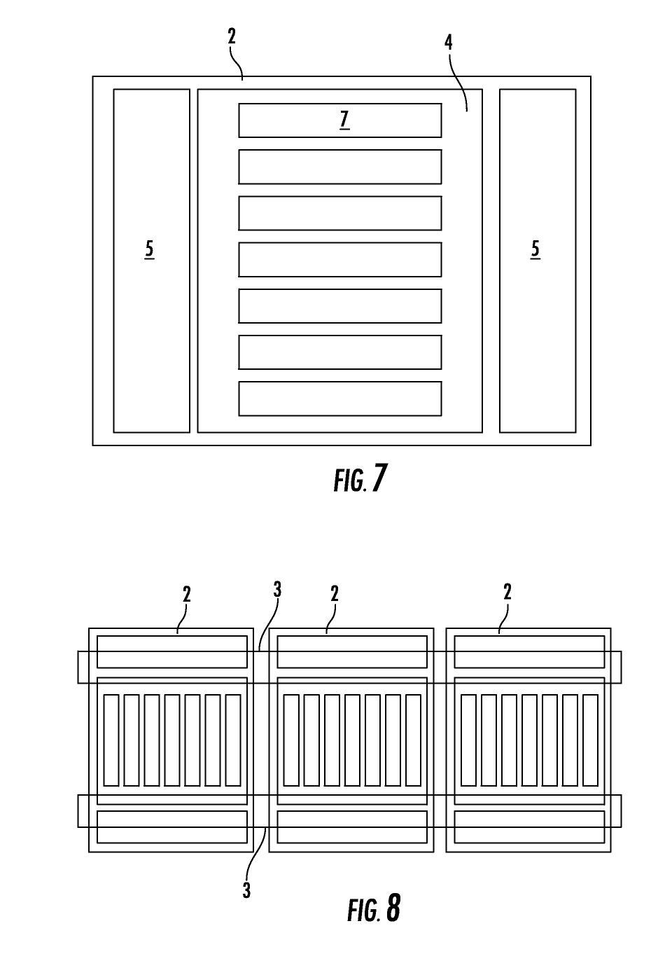

The base back-side metallization 5a at the back-side is thus connected to a base contact structure 5 in each case at two opposite sides by base via structures 5b. As a result, the conductivity is again increased, i.e. losses on account of series resistances are reduced. Furthermore, a series connection 2 of adjacently arranged solar cells 2 by cell connectors running at both edge regions is possible in a simple manner, such that series resistance losses are also reduced with regard to the series connection of the solar cells by cell connectors, as explained below with reference to FIGS. 7 to 9.

FIG. 7 shows a plan view from above of the solar cell in accordance with FIG. 6. In FIG. 8, the solar cell from FIG. 6 is arranged multiply alongside one another in a series and an electrically conductive interconnection of the solar cells 2 by cell connectors 3 is illustrated schematically, wherein continuously parallelepipedal cell connectors 3 are arranged both at an edge region illustrated at the top in FIG. 8 and at an edge region illustrated at the bottom.

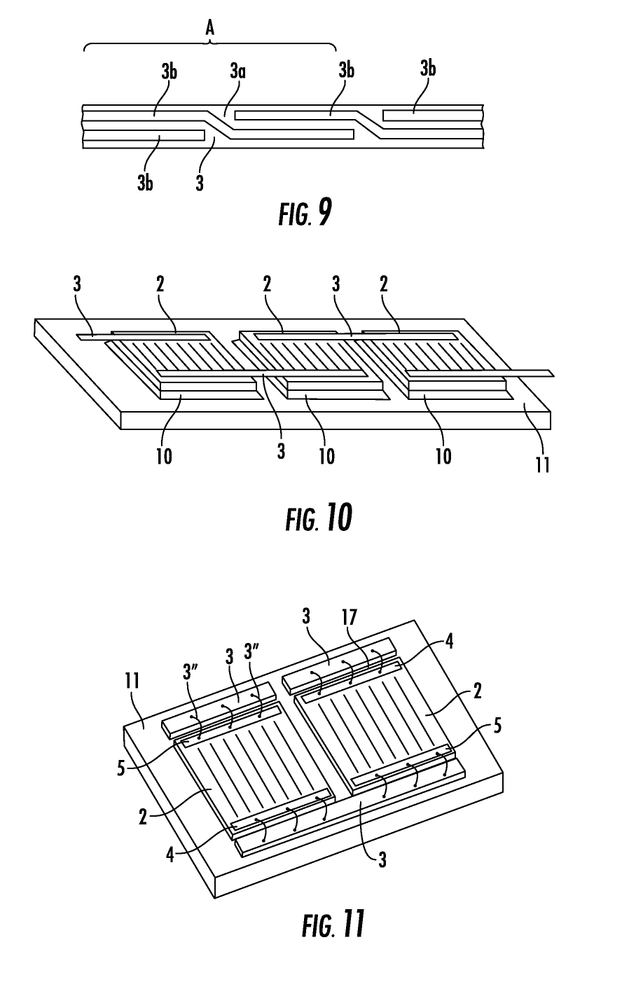

At the side facing the solar cells 2, the cell connectors 3 have the structure illustrated in FIG. 9. The cell connectors 3 consist of an electrically insulating material 3a with metallic conductor tracks 3b embedded therein. Each conductor track 3b spans a region A corresponding approximately to the width of two solar cells 2 arranged alongside one another. A transition region is situated approximately centrally with regard to the longitudinal extent of a conductor track 3b, in which transition region the conductor track 3b changes from an upper region of the cell connector 3 in FIG. 9 to a lower region.

If the cell connector in accordance with FIG. 9 is then applied to the serially arranged solar cells in accordance with FIG. 8, each conductor track 3b of the cell connector in each case connects a base contact structure 5 of a solar cell to the emitter contact structure 4 of the adjacent solar cell. Such a connection is effected at both edge regions, such that a reduction of the series resistance losses is obtained as a result of the doubling of the series connection of the solar cells by the cell connectors 3.

FIG. 10 shows a further detail of this exemplary embodiment of a concentrator system according to the invention in accordance with FIG. 1. The illustration shows solar cells 2 which are connected to cell connectors 3 and which are arranged on a carrier substrate 11 by thermally conductive adhesion promoter 10. The thermally conductive adhesion promoter 10 can be for example an adhesive, a film or a solder, or a combination thereof. The carrier substrate 11 consists of a thermally conductive material and, at the same time, enables an electrical isolation between the individual solar cells 2. Such a material can be, for example, anodized aluminum or coated ceramics. The whole-area connection of each solar cell 2 to the carrier substrate 11 by thermally conductive adhesion promoter 10 results in a thermal contact between each solar cell 2 and the carrier substrate 11 having a low thermal conduction resistance, such that heat is transferred very well from the solar cell 2 to the carrier substrate 11 and, consequently, the heat can be dissipated very efficiently. The solar cells 2 can be designed in accordance with FIG. 2 or in accordance with FIG. 3.

FIG. 11 shows a further exemplary embodiment for the electrical series connection of solar cells 2 arranged in series for a concentrator system according to the invention. In this case, the solar cells 2 can be designed in accordance with FIG. 2, for example, and are arranged as illustrated in FIG. 5, alternately in a manner rotated by 180° in each case, such that an emitter contact structure 4 succeeds a base contact structure 5 alternately at an edge region.

In this exemplary embodiment, the cell connectors 3 likewise span approximately two solar cells 2 arranged alongside one another.

In contrast to the exemplary embodiment illustrated in FIG. 1, however, the cell connectors 3 are not arranged on emitter and base contact structures, but rather laterally alongside the latter. The electrically conductive connection between the cell connector 3 and the respective emitter contact structure 4 and base contact structure 5 is effected by wires 3″ applied e.g. by bonding. This affords the advantage that the current-carrying “cell connector” is arranged alongside the photovoltaically active region and can be given larger dimensions as a result. This gives rise to the fact that the expensive metallic structures on the front side can be reduced in size and a larger photovoltaically active area results.

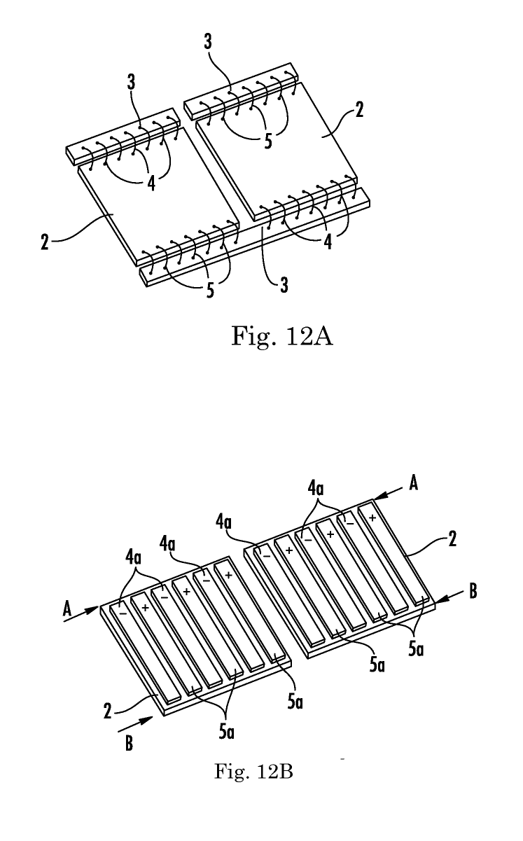

FIG. 12B illustrates a further exemplary embodiment of a solar cell for a concentrator system according to the invention. Two solar cells 2 are shown in rear view. Each of the solar cells 2 has a plurality of base back-side metallizations 5a and emitter back-side metallizations 4a.

The solar cell is correspondingly designed in such a way that base and emitter regions are likewise arranged alternately at the back-side in the semiconductor material of the solar cell, said regions being electrically conductively connected to the respectively underlying back-side metallizations.

At the edge side identified by A, the solar cells in each case have metallic base via structures (not illustrated) which extend approximately perpendicularly proceeding from each of the base back-side metallizations 5a to the front side of the solar cell. Correspondingly, at the opposite edge side B, the solar cells have a plurality of metallic emitter via structures 4b extending in each case approximately perpendicularly from each of the emitter back-side metallizations 4a through the solar cell.

At the front side of the solar cell, metallic contact structures are formed in each case in a punctiform fashion with respect to each via structure, i.e. punctiform base contact structures 5, which are electrically conductively connected to the respective base via structures 5b, and punctiform emitter contact structures 4, which are electrically conductively connected to respective emitter via structures 4b. In this case, the punctiform metallic contact structures 4 and 5 can also be formed from the same material as the via through-contact 4b and 5b, respectively.

With regard to the electrical series connection of the solar cells in the embodiment in accordance with FIG. 12B in the concentrator system, analogously to the illustration in accordance with FIG. 5, the solar cells 2 are arranged serially and alternately in a manner rotated by 180° in each case, such that, at one edge region, the punctiform base contact structures 5 succeed emitter contact structures 4 and, at the opposite edge region, the contact structures likewise succeed one another alternately in the opposite order, as illustrated in FIG. 12A.

This exemplary embodiment involves a modified solar cell structure, compared with the BCBJ structure described previously. In the case of the solar cell structure present here, both polarities are now guided to the front side by via structures. Thus, the designation also changes in accordance with its extended functionality to “front contact back junction metal wrap through” (FCBJ-MWT).

Preferably, the concentrator unit is designed to concentrate incident electromagnetic radiation by a concentration factor in the range of 10 to 100, preferably in the range of 5 to 50. This affords the advantage that silicon-based solar cells can be used, which afford a cost advantage over concentrator units using solar cells based on III-V materials, known from the prior art, in particular since such solar cells require a higher concentration for cost-effective utilization, typically with an irradiation power of significantly greater than 10 W/cm².

Preferably, the concentrator system, in particular the solar cell, is designed to convert electromagnetic radiation in the wavelength range of 300-1200 nm.

The series connection of the solar cells is then effected analogously to FIG. 11.

FIG. 12A illustrates the solar cells from FIG. 12B in front view, with cell connectors 3.

As can be seen in FIG. 12A, the cell connectors 3 are arranged alongside the solar cells 2, and each punctiform base and emitter contact structure is electrically conductively connected to the associated cell connector 3 by a respective bonding wire.

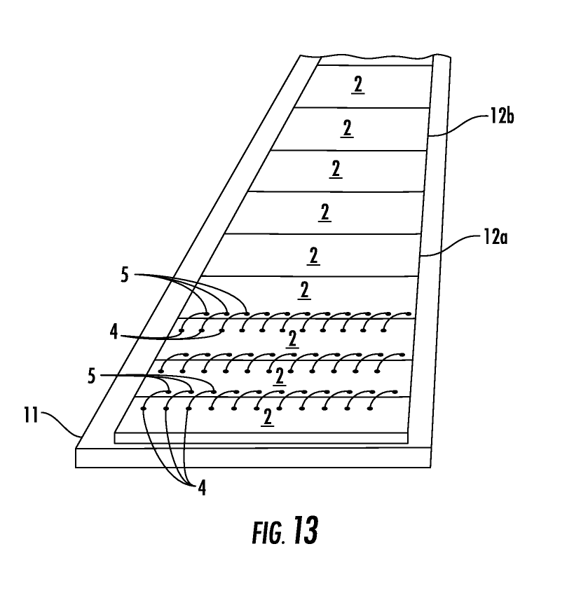

FIG. 13 illustrates a partial view of a further exemplary embodiment of a concentrator system according to the invention.

Since, in the concentrator system according to the invention, base and emitter contact structures are arranged on the front side of the solar cell, it is possible, in a simple manner, to process a plurality of solar cells on a semiconductor substrate, said solar cells being electrically isolated from one another only after the semiconductor substrate or at least part of the semiconductor substrate has been applied to a carrier substrate 11 containing a plurality of solar cells.

It is thus possible firstly for a plurality of solar cell units to be processed on a semiconductor substrate, such as a silicon wafer, for example. The silicon wafer can subsequently be applied to the carrier substrate 11, for example by a thermally conductive but electrically insulating adhesion promoter 10, and, after the application process, the individual solar cells are then electrically insulated for example by sawing or by a laser process.

This production process is known in principle and described for example in WO 2008/107205 A2, in particular on pages 23 and 24, incorporated herein by reference as if fully set forth.

In the case of the exemplary embodiment illustrated in FIG. 13, two silicon wafers 12a and 12b are applied on a carrier substrate 11 by thermally conductive adhesion promoter 10. Use of a solar cell as illustrated in the exemplary embodiment in FIG. 3 or 4 would also be conceivable for this type of interconnection.

Before the silicon wafers are applied, a plurality of solar cells in accordance with FIG. 12A are processed in each of the silicon wafers.

The silicon wafer is subsequently applied to the carrier substrate 11.

After application, electrical isolation of the individual solar cells 2 is obtained by horizontal cuts by a singulation process, for example a sawing process, in accordance with the illustration in FIG. 13. In this case, the thickness of the cutting tool ultimately determines the distance between the cells. As a result, an extremely compact series interconnection by photovoltaically active area can be made possible, in contrast to the method described in WO 2008/107205 A2.

In this exemplary embodiment, the individual solar cells 2 are designed analogously to FIGS. 12A and 12B, such that the emitter contact structures 4 embodied in a punctiform fashion in a solar cell 2 can be electrically conductively connected to the base contact structures 5 embodied in a punctiform fashion in the adjacent solar cell by bonding wires in a simple manner.

In this case, the bonding wires perform the sole function of electrical interconnection and accordingly replace the cell connectors 3.

The rest of the construction of the concentrator unit in accordance with FIG. 13 can be implemented analogously to FIG. 1, i.e. in particular with laterally arranged mirrors.

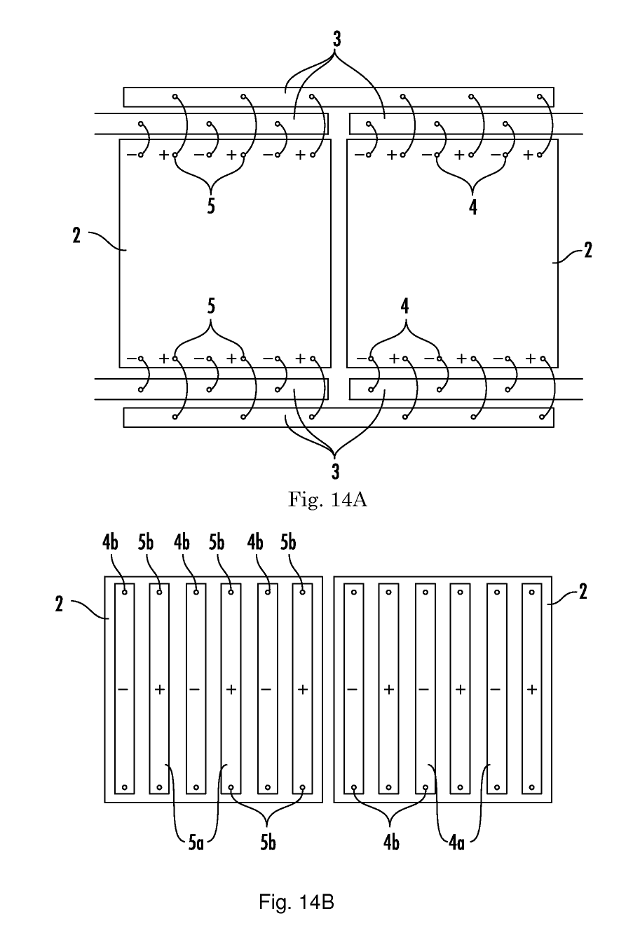

The exemplary embodiment illustrated in FIGS. 14A and 14B is designed substantially analogously to the exemplary embodiment illustrated in FIGS. 12A and 12B. In order to avoid repetition, only the differences will be discussed below. In contrast to the solar cell structure in accordance with FIG. 12B, having a via structure only at an end region of the emitter and base metallizations, the solar cells in accordance with FIG. 14B have a via structure in each case at both end regions.

The solar cells 2 in this exemplary embodiment have an emitter via structure 4b in each case at two opposite end regions of the emitter back-side metallizations 4a and likewise have a base via structure 5b in each case at two opposite end regions of the base back-side metallizations 5a. Accordingly, punctiform emitter contact structures 4 are arranged with respect to each emitter via structure 4b at the front side and punctiform base contact structures 5 are arranged with respect to each base via structure 5b at the front side.

The series interconnection in the module can be effected in accordance with FIG. 14a by, on each side, in each case two parallel, partly overlapping cell connectors 3. In this instance, in each case an inner cell connector is electrically conductively connected to the emitter contact structures 4 of a first solar cell and the base contact structures 5 of an adjacent second solar cell. In opposite polarity, the respective outer cell connector connects the base contact structures 5 to the emitter contact structures 4 of a further adjacent third solar cell. This affords the advantage of effectively shortening the current paths and thus reducing the electrical resistance.

In FIGS. 2, 3 and 6, the base via structure 5b is embodied such that it slightly covers the front side of the solar cell (reference sign 5′ in FIGS. 2 and 6), thus resulting in a good contact-making capability for the base contact structure 5.

### LIST OF REFERENCE SIGNS

(1) Optical unit, optical structure
(2) Solar cell
(3) Cell connector
(4) Emitter contact structure
(4a) Emitter back-side metallization
(4b) Emitter via structure
(5) Base contact structure
(5a) Base back-side metallization
(5b) Base via structure
(6) Silicon wafer
(7) Emitter
(8) Base
(9) Bypass diode
(10) Adhesion promoter
(11) Carrier substrate
(12a) Silicon wafer
(12b) Silicon wafer

1. A concentrator system, comprising
an optical concentrator unit and a receiver, said receiver has a carrier substrate (11) and at least one photovoltaic solar cell (2), the optical concentrator unit and the receiver are arranged in an interacting fashion such that during use of the concentrator system incident electromagnetic radiation is concentrated by the concentrator unit onto at least one partial region of a front side of the solar cell (2) facing the incident radiation during use, and
said solar cell (2) is a photovoltaic semiconductor solar cell, having at least one base region and at least one emitter region and also at least one metallic base contact structure (5), which is electrically conductively connected to the base region and is designed for external electrical interconnection, and having at least one metallic emitter contact structure (4), which is electrically conductively connected to the emitter region and is designed for external electrical contact-making,
the base contact structure (5) and the emitter contact structure (4) are arranged indirectly or directly on the front side of the solar cell (2),
at least one base back-side metallization (5a), which is electrically conductively connected to the base (8), is arranged indirectly or directly at a back-side of the solar cell (2), and
the solar cell (2) has at least one metallic base via structure (5b), said base via structure (5b) extends from the base back-side metallization to the base contact structure (5), such that base back-side metallization (5a) and base contact structure (5) are electrically conductively connected by the base via structure (5b).

2. The concentrator system as claimed in claim 1, wherein the solar cell (2) comprises a silicon substrate, the base is formed in said substrate.

3. The concentrator system as claimed in claim 2, wherein the solar cell (2) is designed such that during use generation of charge carrier pairs takes place substantially in the silicon substrate.

4. The concentrator system as claimed in claim 1, wherein the base via structure is arranged at an edge region of the solar cell (2).

5. The concentrator system as claimed in claim 1, wherein the base via structure (5b) is formed in a manner penetrating through the base (8).

6. The concentrator system as claimed in claim 1, wherein the base back-side metallization (5a) is connected to a heat dissipating substrate.

7. The concentrator system as claimed in claim 1, wherein the solar cell (2) comprises a semiconductor layer, at the back-side of which at least one base region and at least one emitter region are formed, and the solar cell (2) comprises an emitter back-side metallization (4a) and also at least one metallic emitter via structure (4b), the emitter back-side metallization (4a) is arranged indirectly or directly at the back-side of the semiconductor layer and is electrically conductively connected to the emitter region, and the emitter via structure extends from the emitter back-side metallization (4a) to the emitter contact structure (4), such that emitter back-side metallization (4a) and the emitter contact structure (4) are electrically conductively connected by the emitter via structure (4b).

8. The concentrator system as claimed in claim 7, wherein a plurality of alternately arranged ones of the emitter and the base back-side metallizations (4a, 5a) are arranged at the back-side of the solar cell (2), and the emitter and the base back-side metallizations (4a, 5a) extend parallel to one another.

9. The concentrator system as claimed in claim 8, wherein each of the emitter back-side metallizations (4a) is connected to in each case at least one emitter via structure (4b) and each of the base back-side metallizations (5a) is connected to in each case at least one base via structure (5b).

10. The concentrator system as claimed in claim 1, wherein the receiver comprises a plurality of the solar cells (2) which are electrically interconnected to form a solar cell module, and the solar cells (2) are arranged serially as a solar cell series.

11. The concentrator system as claimed in claim 10, wherein the serially arranged solar cells (2) in each case have the emitter and the base contact structures (4, 5) at the front side at at least one outer region of the solar cell series, and in each case the emitter contact structure (4) of one of the solar cells (2) is electrically conductively connected to the base contact structure (5) of the following solar cell (2) by a cell connector (3, 3′, 3″).

12. The concentrator system as claimed in claim 10, wherein a cell connector (3, 3′, 3″) is in each case arranged at both sides alongside the solar cell series, said cell connector extending over two of the solar cells (2), and the solar cells (2) are electrically conductively connected to the cell connector (3, 3,′, 3″).

13. The concentrator system as claimed in claim 10, wherein the solar cells (2) of the solar cell series in each case have the emitter contact structure (4) at one edge region and the base contact structure (5) at an opposite edge region, and the solar cells (2) are arranged alternately with regard to the contact structures, in such a way that a cell connector (3, 3′, 3″) extending approximately rectilinearly over an edge region of the solar cell series in each case connects the emitter contact structure (4) to the base contact structure (5) of the neighboring solar cell (2).

14. The concentrator system as claimed in claim 1, wherein the concentrator unit is designed to concentrate incident electromagnetic radiation by a concentration factor in a range of 10 to 100.

15. The concentrator system as claimed in claim 1, wherein the concentrator system is designed to convert electromagnetic radiation in a wavelength range of 300-1200 nm.

16. The concentrator system as claimed in claim 1, wherein the solar cell (2) comprises a silicon substrate, and the base and the emitter (7) are formed in the silicon substrate.

17. The concentrator system as claimed in claim 5, wherein the solar cell (2) comprises a plurality of the base via structures (5b) which in each case penetrate through the base (8), approximately perpendicularly to the back-side, and the base via structure penetrates through at least the photovoltaically active base region.
